(19) United States
(12) Patent Application Publication
(10) Pub. No.: US 2006/0063318 A1
(43) Pub. Date: Mar. 23, 2006

(54) Reducing ambipolar conduction in carbon nanotube transistors

(76) Inventors: Suman Datta, Beaverton, OR (US); Jack Kavalieros, Portland, OR (US); Mark L. Doczy, Beaverton, OR (US); Matthew V. Metz, Hillsboro, OR (US); Marko Radosavljevic, Beaverton, OR (US); Amlan Majumdar, Portland, OR (US); Justin K. Brask, Portland, OR (US); Robert S. Chau, Beaverton, OR (US)

Correspondence Address: TROP PRUNER & HU, PC, 8554 KATY FREEWAY, SUITE 100, HOUSTON, TX, 77024, US

(21) Appl. No.: 10/938,778

(22) Filed: Sep. 10, 2004

(51) Int. Cl. H01L 21/336; H01L 21/8234

(52) U.S. Cl. 438/197

(57) ABSTRACT

Ambipolar conduction can be reduced in carbon nanotube transistors by forming a gate electrode of a metal. Metal sidewall spacers having different workfunctions than the gate electrode may be formed to bracket the metal gate electrode.

### BACKGROUND

This invention relates generally to carbon nanotube transistors.

Carbon nanotube transistors have advantageous properties compared to conventional silicon based transistors due to the inherent high mobility of both electrons and holes in carbon nanotubes, but suffer from ambipolar conduction. The ambipolar conduction is a result of the presence of Schottky barrier metal source drains causing significant barrier thinning at the drain end with zero gate bias and high drain bias. This results in a relatively high off current and a low on-to-off current ratio. Ambipolar conduction is particularly problematic in pass transistor logic applications, such as transmission gates, pass transistors, and static random access memory cells.

Thus, there is a need for carbon nanotube transistors with reduced ambipolar conduction.

### BRIEF DESCRIPTION OF THE DRAWINGS

FIG. 1 is a schematic depiction of a carbon nanotube transistor, in accordance with one embodiment of the present invention, showing the effect in an n-channel carbon nanotube transistor and on electron tunneling from the metal source-drain underneath the metallic spacers to create an electrostatically induced source drain extension;

FIG. 2a is a hypothetical energy band diagram with zero gate bias;

FIG. 2b is a hypothetical energy band diagram with gate bias under the threshold voltage;

FIG. 2c is a hypothetical energy band diagram with gate bias greater than the absolute value of the threshold voltage;

FIG. 3 is an enlarged, cross-sectional view of an early stage of manufacture of the embodiment shown in FIG. 1;

FIG. 4 is an enlarged, cross-sectional view at a subsequent stage of manufacture of the embodiment shown in FIG. 1;

FIG. 5 is an enlarged, cross-sectional view at still a subsequent stage;

FIG. 6 is an enlarged, cross-sectional view at still a subsequent stage; and

FIG. 7 is an enlarged, cross-sectional view at a subsequent stage of manufacture.

### DETAILED DESCRIPTION

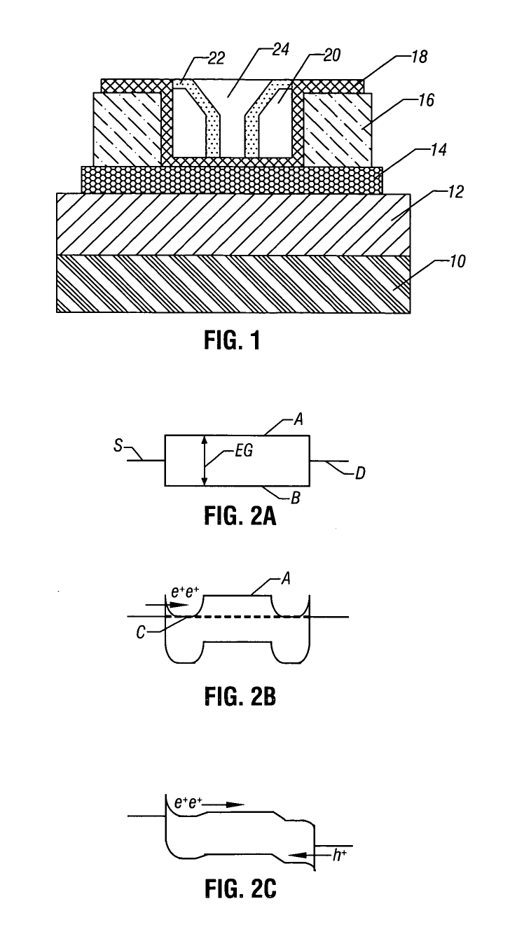

Referring to FIG. 1, a carbon nanotube field effect transistor may include a p-type or n-type silicon substrate 10 covered by silicon dioxide layer 12. In one embodiment, a silicon-on-insulator (SOI) substrate is utilized. The carbon nanotubes 14 are arranged on top of the oxide 12. A metal source drain 16 is patterned on top of the carbon nanotubes 14. A layer of high dielectric constant material 18 is formed over the source drains 16.

Metal spacers 20 are formed thereover. The spacers 20 may be covered by a silicon nitride layer 22. A mid gap workfunction metal gate electrode 24 is then formed, thus, having a different workfunction than that of the spacers 20.

The conduction between the source (S) and drain (D) 16 is such that electrons tunnel under the spacer 20 causing inversion underneath the metallic spacer 20. The bulk part of the transistor's channel is not inverted and provides a thermionic barrier just like a silicon p-n junction field effect transistor.

As shown in the energy band diagram of FIG. 2A, with no gate bias, the energy gap, EG, between bands A and B, is sufficient to block electron and hole flow in the channel between source (S) and drain (D) 16. The band A, the higher energy band, is the conduction band and the band B is the valence band.

With a gate bias less than the threshold voltage, as shown in FIG. 2B, electrons are able to tunnel under the region below the spacers 20 because of the relatively lower energy band at C, due to the spacer 20 workfunction. In effect, the spacers 20 induce source drain extensions because the metallic sidewall spacers 20 have a lower workfunction in the case of an n-channel device. Thus, a higher energy band, indicated at A in FIG. 2B, is provided by the mid gap workfunction metal gate electrode 24.

With a gate bias greater than the threshold voltage (FIG. 2C) electron conduction (e⁺e⁺) can occur because of the reduced energy gap. However, hole conduction (h⁺) is blocked.

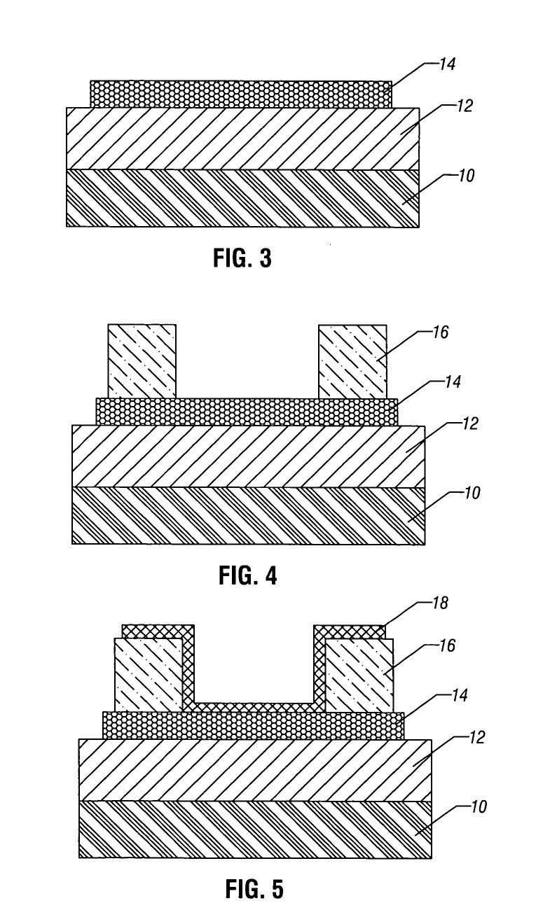

Referring to FIG. 3, initially, the silicon-over-insulator structure includes the substrate 10 and the oxide 12. The top silicon layer of a silicon over insulator structure may be removed and replaced by deposited, single walled carbon nanotubes 14. A metal source drain 16 is then deposited, as shown in FIG. 4, and patterned through evaporation and liftoff. In one embodiment, the source drain 16 may be formed of the same metal as the spacer 20.

Referring to FIG. 5, a high dielectric constant material 18 may be patterned using atomic layer deposition. By a high dielectric constant, it is intended to refer to materials having a dielectric constant greater than 10. Examples of such materials include metal oxides such as hafnium oxide, hafnium silicon oxide, lanthanum oxide, lanthanum aluminum oxide, zirconium oxide, zirconium silicon oxide, titanium oxide, tantalum oxide, barium strontium titanium oxide, barium titanium oxide, strontium titanium oxide, yttrium oxide, aluminum oxide, lead scandium oxide, and lead zinc niobate.

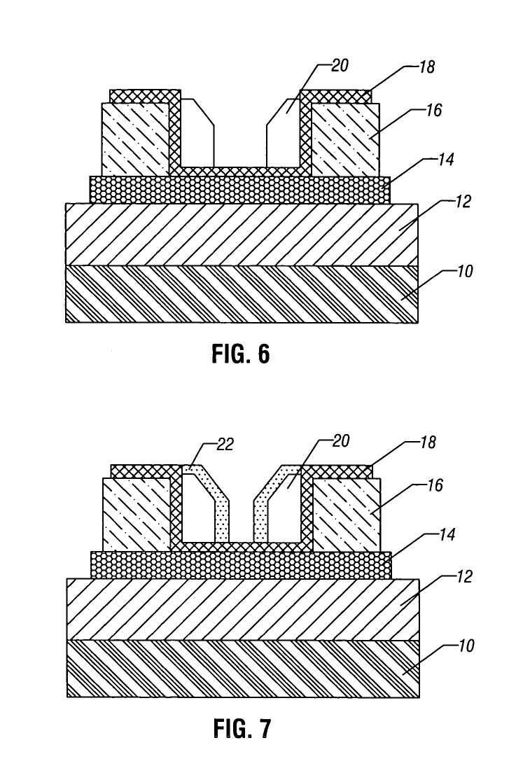

Then, referring to FIG. 6, a lower workfunction metal may be deposited and anisotropically etched selective to the high dielectric constant dielectric layer 18 to form spacers 20 for an n-channel device. By lower workfunction metal, it is intended to refer to a material having a workfunction of less than the workfunction of the gate electrode 24. For example, with gate electrode 24 having a workfunction of about 4 to about 5 eV, the spacer 20 workfunction may be from about 3.8 to about 4.0 eV. Examples of suitable metals for the p-channel spacer 20 include aluminum, titanium, hafnium, and alkali metals such as sodium, potassium, and lithium. Metals with higher workfunctions may be doped with lower electro-negativity material to reduce their workfunctions and vice versa.

For a p-channel device, the spacer 20 workfunction is higher than the workfunction of the gate electrode 24. For example, the spacer 20 may have a workfunction of from about 5.0 to about 5.2 eV in one embodiment. Examples of metals for a spacer 20 in an n-channel device include nickel, molybdenum, ruthenium, rhodium, palladium, antimony, tungsten, rhenium, or platinum.

Then, referring to FIG. 7, a second silicon nitride layer 22 may be deposited. The silicon nitride layer 22 may be deposited by atomic layer deposition or chemical vapor deposition, as two examples. The layer 22 is etched selectively to the high-K dielectric constant material 18.

Then, referring to FIG. 1, the mid gap workfunction metal gate electrode 24 may be deposited. The gate electrode 24 may be deposited by chemical vapor deposition for example. Suitable workfunctions to the metal gate electrode are from about 4.4 to about 4.6 eV. Suitable metals for the gate electrode 24 include aluminum, titanium, tantalum, tungsten, ruthenium, palladium, molybdenum, niobium, and alloys thereof and metal compounds including those metals. Suitable doping materials for reducing the workfunction of a gate metal include lanthanide metals, scandium, zirconium, hafnium, cerium, aluminum, titanium, tantalum, niobium, tungsten, alkali metals, and alkali earth metals. The doping may be done by furnace diffusion implantation, or introducing dopants during plasma deposition, to mention a few examples. After deposition, the gate electrode 24 may be chemically mechanically polished using the nitride and/or the high-K dielectric as a polish stop layer.

The action of the spacers 20 induces source drain extensions in the Schottky barrier source drain carbon nanotube transistor. This reduces or eliminates ambipolar conduction. As a result, in some embodiments, an improved ratio of on-to-off current may be achieved.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a carbon nanotube transistor with a metal gate electrode and a sidewall spacer formed of a metal having a workfunction different than the workfunction of said gate electrode.

2. The method of claim 1 including forming a p-channel transistor with the workfunction of said spacer being higher than the workfunction of the gate electrode.

3. The method of claim 1 including forming an n-channel transistor with the workfunction of said spacer being lower than the workfunction of said gate electrode.

4. The method of claim 3 including forming said spacers with a workfunction from about 3.8 to about 4.0 eV.

5. The method of claim 4 including forming said gate electrode with a workfunction from about 5.0 to about 5.2 eV.

6. The method of claim 1 including depositing metal to form source drains for said transistor.

7. The method of claim 1 including forming a dielectric between said spacer and said gate electrode.

8. The method of claim 7 including using silicon nitride as said dielectric.

9. The method of claim 1 including forming said transistor using a silicon over insulator substrate.

10. The method of claim 1 including depositing and patterning metal over said carbon nanotubes to form a source and drain.

11. A transistor comprising:
a support;
carbon nanotubes formed over said support;
a metal gate electrode formed over said carbon nanotubes;
a source and drain formed over said carbon nanotubes; and
a sidewall spacer between said gate electrode and said source and drain, said sidewall spacer having a workfunction different than the workfunction of said gate electrode.

12. The transistor of claim 11 wherein said transistor is a p-channel transistor and the workfunction of said gate electrode is lower than the workfunction of said spacer.

13. The transistor of claim 11 wherein said transistor is an n-channel transistor and the gate electrode has a workfunction higher than the workfunction of said spacer.

14. The transistor of claim 13 wherein said spacer has a workfunction from about 3.8 to about 4.0 volts.

15. The transistor of claim 14 wherein the gate electrode has a workfunction from about 4.4 to about 4.6 electron volts.

16. The transistor of claim 11 wherein said source and drain are formed of metal.

17. The transistor of claim 11 including a dielectric between said spacer and said gate electrode.

18. The transistor of claim 17 wherein said dielectric includes silicon nitride.

19. The transistor of claim 11 wherein said support includes a silicon over insulator substrate.

20. The transistor of claim 11 including a gate dielectric having a dielectric constant greater than ten, said dielectric between said gate electrode and said carbon nanotubes.

21. A method comprising:
reducing ambipolar conduction by causing electrons to tunnel under a region between the source and the gate electrode of a carbon nanotube transistor.

22. The method of claim 21 including causing said electrons to tunnel under a metallic spacer between said source and said gate electrode.

23. The method of claim 22 including providing a spacer which has a different workfunction than the workfunction of said gate electrode.

24. The method of claim 23 including providing a spacer with a higher workfunction than said gate electrode.

25. The method of claim 23 including providing a spacer with a workfunction lower than the workfunction of said gate electrode.
